(19) United States
(12) Patent Application Publication
(10) Pub. No.: US 2013/0276984 A1
(43) Pub. Date: Oct. 24, 2013

(54) COATING APPARATUS HAVING A HIPIMS POWER SOURCE

(71) Applicants: Frank Papa, Venlo (NL); Roel Tietema, Venlo (NL); Anthonie Kaland, Eindhoven (NL)

(72) Inventors: Frank Papa, Venlo (NL); Roel Tietema, Venlo (NL); Anthonie Kaland, Eindhoven (NL)

(73) Assignee: Hauzer Techno Coating BV, Venlo (NL)

(21) Appl. No.: 13/575,709

(22) PCT Filed: Jan. 27, 2011
(86) PCT No.: PCT/EP2011/000372

§ 371 Date: Oct. 22, 2012

(30) Foreign Application Priority Data
Dec. 29, 2010 (DE) 20 2010 001 497.2

(51) Int. Cl. C23C 16/02

(52) U.S. Cl. CPC C23C 16/0245
USPC 156/345.43

(57) ABSTRACT

A coating apparatus having a vacuum chamber, a plurality of cathodes arranged therein and also a HIPIMS power source, characterized in that in addition to at least one coating cathode which can be operated with the HIPIMS power source a plurality of etching cathodes is provided which are smaller in area in comparison to the coating cathode, with the etching cathodes being connectable in a predetermined or predeterminable sequence to the HIPIMS power source.

The present invention relates to a coating apparatus having a vacuum chamber, a plurality of cathodes arranged therein and also a HIPIMS power source. An apparatus of this kind is described in the international patent application with the publication number WO 2007/115819 and is in other respects also known from the European patent specification 1 260 603.

Whereas WO 2007/115819 is predominantly concerned with the design of the voltage source for the substrate bias, the present application is concerned with the design of the HIPIMS power source which is used to apply electrical power to the coating cathode or to the coating cathodes.

Originally one was concerned with so-called HIPIMS sputtering processes (HIPIMS signifies High Power Impulse Magnetron Sputtering) for the coating of workpieces. However, in the named EP patent specification 1 260 603 the use of HIPIMS is described in the context of a pretreatment of the substrates or the workpieces in the form of an etching treatment.

Under etching one understands the cleaning of the surface of the substrates or of the workpieces by means of highly energetic ions which strike the surface in the plasma of a vacuum chamber in order, on the one hand, to remove contaminants or surface material and, on the other hand, to implant the ions which are carrying out the etching treatment into surface regions of the substrates of the workpieces. When the etching process is carried out with the same ions that are intended for the coating at the workpieces or with other compatible elements, a transition layer arises from the substrate to the coating with, for example, an increased concentration of the element used for the coating, or of the elements provided for the adhesion of the coating, and this leads to an improved adhesion of the actual coating to the substrates or to the workpieces.

In the coating mode cathodes of the coating material which have a relatively large surface are used at least in large plants.

For a given HIPIMS power source the coating takes place with a current density or power density which is determined by the size or power capability of the HIPIMS power source and the area of the cathode. The corresponding current density or power density is however not ideal for the etching process.

The object of the present invention is to design a coating apparatus of the initially named kind so that it is better designed for the etching process and operates more effectively.

In order to satisfy this object a coating apparatus of the initially named kind is provided in which, in addition to at least one coating cathode which can be operated with the HIPIMS power source, a plurality of cathodes are provided which are smaller an area in comparison to a coating cathode and which can be connected in a predetermined or predeterminable sequence to the HIPIMS power source.

In this way, in accordance with the invention, it is possible to achieve a substantially higher peak current density or power density at the individual etching cathodes which are of smaller area, whereby the etching process runs better and more effectively. In order to achieve this, it is simply necessary to provide a switching device which applies the impulses of the HIPIMS power source one after the other to the respective etching cathodes, so that preferably a maximum of one etching cathode is fed with power at any point in time. In this connection an electronic switching device can, for example, serve for the distribution of the individual HIPIMS impulses to the individual cathodes.

Through the arrangement in accordance with the invention the same HIPIMS power source can also be used for the etching cathodes which is used for the coating cathode, without the HIPIMS power source having to be made larger, whereby considerable costs and complexity can be saved.

As a rule, in PVD plants in general and in sputter plants or arc coating plants in particular, the individual substrates or workpieces are arranged on a rotatable table, whereby the individual workpieces are frequently also themselves rotated about their own axis during the coating. Since the workpiece table, or the holder of the workpieces, rotates about the longitudinal axis of the vacuum treatment chamber and the individual workpieces also possibly rotate about their own axes parallel to the longitudinal axis of the vacuum chamber, any irregularities in the coating flux from the coating cathodes or in the flux of etching ions during the etching process is compensated so that the substrates are uniformly treated or coated over their surface. As a consequence it is not disturbing when the individual etching cathodes, which necessarily have to be arranged spatially somewhat separated from one another, each only treat some of the workpieces but not all of them because, through the sequential connection of the HIPIMS power source to the individual etching cathodes, in total, i.e. seen in time average, a uniform etching treatment of the substrates or the workpieces can be achieved.

The etching cathodes can also be used as coating cathodes. For this purpose they can also be connected together and fed jointly with the power pulses of the HIPIMS power source. They could however also be fed sequentially from the HIPIMS power source, then the usually with a reduced power matched to the coating process. As a consequence, the etching cathodes do not exclusively have to be used for the etching treatment, but rather they can also be used for coating and so the advantage arises that the spatially separated arrangement of the etching cathodes does not lead to an irregular coating as a result of the movement of the substrates or workpieces in the treatment chamber.

It is particularly preferred when the coating apparatus is characterized in that the HIPIMS power source consists of a DC part and a switching part which generates power impulses for the predetermined frequency for the coating cathode and in that, during operation of the coating apparatus in the etching mode, the power impulses are applied with the predeterminable frequency to the individual etching cathodes in a predetermined or predeterminable sequence whereby the etching cathodes are successively fed with individual power impulses of the HIPIMS power source.

This embodiment is particularly simple to realize because no technical changes to the HIPIMS power source are necessary, but rather it is only necessary to provide an additional switching device in order to apply the individual power impulses of the HIPIMS power source to the etching cathodes in the predetermined manner, i.e. in the predeterminable sequence. This switching device can be realized separately from the HIPIMS power source or as a component of the HIPIMS power source.

An alternative coating apparatus is characterized in that the HIPIMS power source consists of a DC part and a switching part which generates power impulses with a predetermined frequency for the coating cathode and that in the etching mode the HIPIMS power source can be so operated that it delivers at least further impulses between the power impulses of the predeterminable frequency and in that the impulses delivered in total are applied in sequence to the etching cathodes one after the other, whereby the etching cathodes are successively fed with the individual impulses of the HIPIMS power source.

Here the switching part of the HIPIMS power source must admittedly be slightly changed in order to generate the further power impulses. Depending on the specific design of the HIPIMS power source, this can lead to an additional complication in the switching part and it can also possibly be necessary to increase somewhat the power capability of the DC part of the HIPIMS power source (of the DC part). In total a substantially more effective and more rapid etching process is made possible with little cost and complexity. It should however also be stated that the DC part of the HIPIMS power source is in the part where most of the costs arises. The switching part is relatively cost favorable and be straightforwardly designed and also work at or be operated with a higher predetermined frequency, so that the further impulses are available without this leading to considerable costs.

A further coating apparatus is characterized in that the HIPIMS power source consists of a DC part and a switching part which generates power impulses of the predetermined frequency for the coating cathode. Thus, in the etching mode, the HIPIMS power source can be operated in such a way that it delivers further impulses between the power impulses with the predetermined frequency and in that the impulses which are delivered in total are applied in groups to the etching cathodes in sequence, whereby the etching cathodes are successively fed with the individual groups of impulses.

This variant provides that, instead of feeding the etching cathode with one power impulse and then switching immediately to the next etching cathode, a plurality of impulses can be applied to the first etching cathode, i.e. groups of impulses, and only then is a switch made to the next etching cathode which is correspondingly feedable with groups of impulses.

When this procedure is used together with the rotation of the substrates on the workpiece table or on the workpiece holder and when the movement of the workpiece table or of the workpiece holder about the longitudinal axis of the chamber is used, then a uniform etching treatment can also be achieved with this variant.

The invention will subsequently be explained in more detail with reference to embodiments and to the drawings in which are shown:

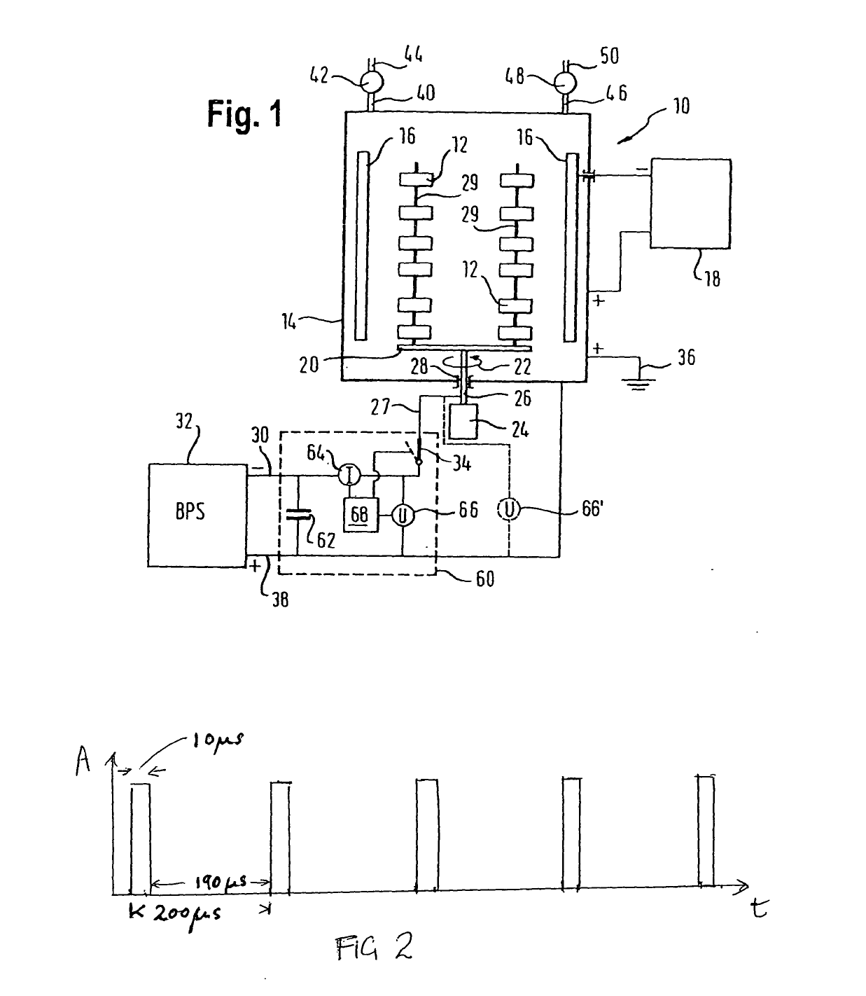

FIG. 1 the FIG. 1 of WO 2007/115819 which shows the basic design of a magnetron sputtering plant with a HIPIMS power source,

FIG. 2 a representation of the power impulse sequence of a HIPIMS power source such as can be used in the apparatus in accordance with FIG. 1 and in the present invention,

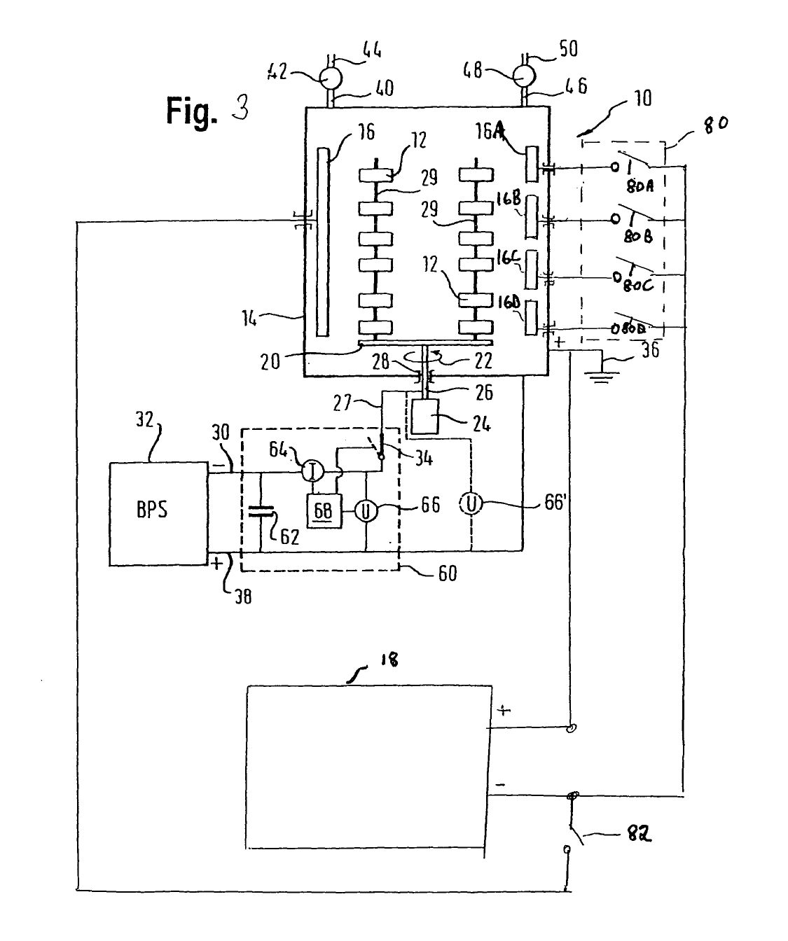

FIG. 3 a representation similar to that of FIG. 1 but of a coating apparatus in accordance with the invention,

FIG. 4 a representation similar to FIG. 2 but here in order to show how the impulse sequence of the HIPIMS power impulses is applied to the individual etching cathodes,

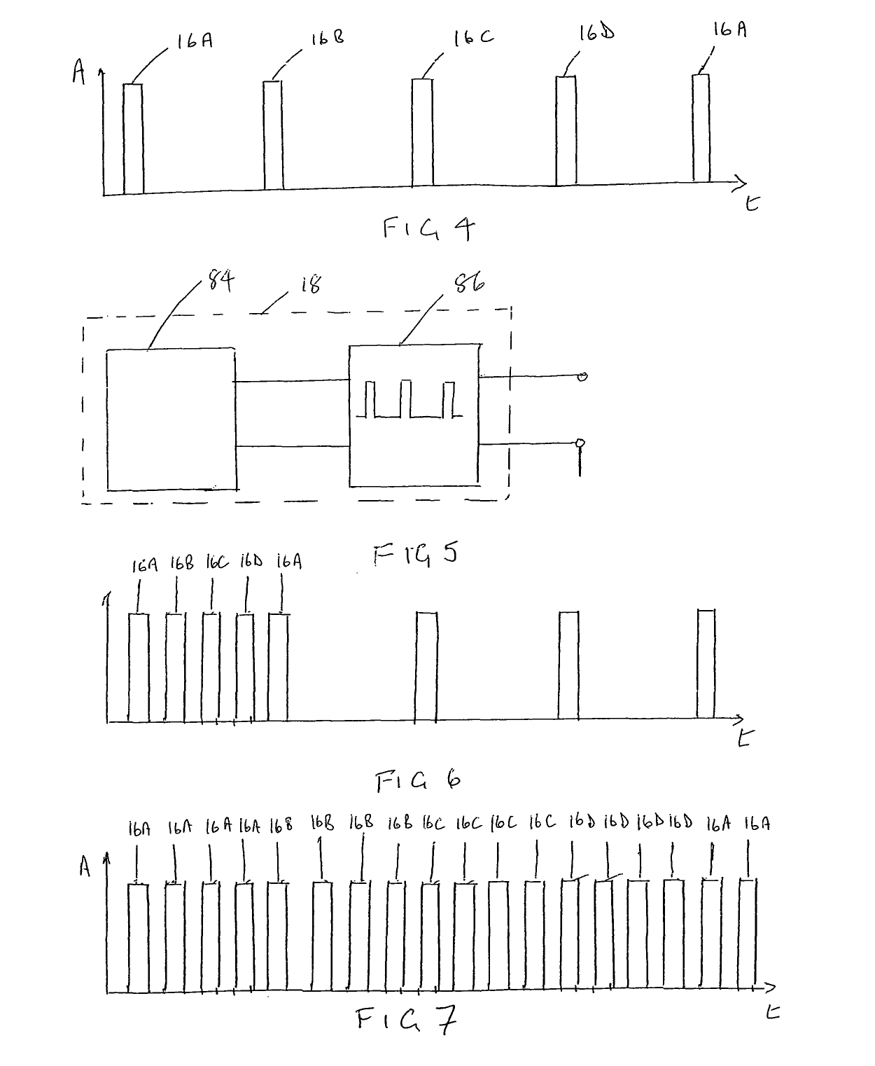

FIG. 5 a block circuit diagram to illustrate the design of the HIPIMS power source which can be used in the coating apparatus in accordance with the invention, and

FIG. 6 a representation similar to FIG. 4 but to show how additional impulses can be produced by the HIPIMS power source and in order to show how such further impulses can be applied to the individual etching cathodes.

FIG. 7 a further representation similar to FIG. 5 in order to show how the individual impulses of the HIPIMS power source can be applied group-wise to individual etching cathodes.

Referring to FIG. 1 a vacuum coating apparatus 10 is shown there for the treatment and coating of a plurality of substrates 12. The apparatus consists of a vacuum chamber 14 of metal, which in this example has two oppositely disposed cathodes 16 which are respectively equipped with their own HIPIMS power source 18 (of which only one is shown here) for the purpose of generating ions of a material which is present in the gas phase in the chamber and/or ions of a material from which the respective cathode or cathodes is or are formed. The substrates (workpieces) 12 are mounted on a substrate carrier 20 in the form of a table which can be rotated in the direction of the arrow 22 by an electric motor 24 which drives a shaft 26 which is connected to the substrate carrier. The shaft 26 passes through a lead-through 28 at the base of the chamber 14 in a sealed and insulated manner which is well known per se. This permits a terminal 30 of a substrate bias supply 32 to be connected via a line 27 to the substrate carrier 20. This substrate bias supply 32 is designated here with the letters BPS which represents an abbreviation for Bias Power Supply. The substrates 12 which are mounted on the vertical columns 29 are hereby kept at the voltage which is applied to the terminal 30 of the bias power supply 32 when the switch 34 is closed.

In this example, the metallic housing 14 of the apparatus 10 is connected to earth 36 and also, at the same time, the positive terminal of the apparatus. The positive terminal of the HIPIMS power source 18 is likewise connected to the housing 14 and thus to the earth 36, as is also the positive terminal 38 of the substrate bias supply 32.

At the upper part the vacuum chamber (although this position is not critical) has a connection stub 40 which is connected via a valve 42 and a further line 44 to a vacuum system for the purpose of evacuating the treatment chamber 14. The vacuum system is not shown but is well known in this field. A further line 50 which enables the supply of one or more suitable gases into the vacuum chamber is likewise connected to the upper part of the vacuum chamber via a valve 48 and a connection stub 46. For example, an inert gas such as argon can be introduced into the vacuum chamber or a gas such as nitrogen or acetylene for the deposition of nitrides or carbon coatings or carbo-nitride coatings by reactive sputtering. Separate connections, similar to the connections 46, 48, 50, can be provided for the different gases if required.

Vacuum coating apparatuses of the generally described kind are known in the prior art and are frequently equipped with more than two cathodes 16. For example a vacuum coating apparatus available from the company Hauzer Techno Coating BV in which the chamber 10 has a generally octangular shape in cross-section with four doors which open outwardly of which each carries a magnetron cathode 16. These cathodes can consist of the same material; however, they frequently consist of different materials in order to be able to build up coatings of the different materials in layers on the substrates or articles such as 12.

A typical vacuum coating apparatus include also a plurality of further devices which are not shown in the schematic drawing of FIG. 1 such as dark field screens, heating devices for the preheating of the substrates 12 and sometimes electron beam sources or plasma sources in diverse forms. In addition it is possible to provide arc cathodes in addition to magnetron sputtering cathodes in the vacuum coating apparatus. When using the apparatus the air which is initially present in the vacuum chamber 14 is evacuated by the vacuum pumping system via the line 44, the valve 42 and the line 40 and an inert gas such as argon and/or active gases flow into the chamber via the line 50, the valve 48 and the connection stub 46. In this connection the air which is initially present in the chamber is removed from it and the vacuum chamber 14 is flushed with inert gas and/or with reactive gases. At the same time, or following this, the heating devices (not shown) can be operated in order to preheat the substrates and to drive out any volatile gases or compounds which are present at the articles 12.

The inert gas which is introduced into the chamber is necessarily ionized to a certain degree, for example as a result of cosmic radiation and splits into electrons and inert gas ions, for example argon ions. The argon ions are attracted to the cathodes and collide there with the material of the target, i.e. of the cathodes, whereby ions are knocked out of the cathode material and the secondary electrons are generated. A magnetron system (not shown, but well known per se) is associated with each of the cathodes and normally generates a magnetic tunnel in the form of a closed loop which extends over the surface of the cathode. This magnetic tunnel present as a closed loop forces electrons to move in orbits around the closed loop and to generate further ionization by collisions. These secondary electrons thus lead to further ionization of the gas atmosphere of the chamber which in turn leads to the generation of further inert gas ions and ions of the material of the cathode 16. These ions can be attracted to the articles 12 by the substrate bias at a suitable level, for example a level of −700 to −1200 V and caused to strike the articles with adequate energy and to etch the surface of the articles.

As soon as the etching treatment has been completed a switch can be made to the coating mode in which, with a suitable power supply for the cathodes, a flux of atoms and ions of the cathode material moves into the space which is occupied by the workpieces 12 which rotate on the substrate carrier. The substrates are then coated with the material of the cathode. If a reactive gas such as acetylene is present in the vacuum chamber then the corresponding coating forms on the substrates. When, for example, the cathode exists of Ti, then the acetylene (C₂H₂) is split up into C atoms and H atoms and a coating of TiC arises on the workpieces. The hydrogen is partly deposited in the coating and partly removed by the vacuum system from the vacuum chamber. The movement of the ions in the direction of the substrates 12 on the substrate carrier 20 is brought about by the negative bias which is applied to the substrate holder, i.e. to the substrates. Other non-ionized material atoms of the cathode 16 receive adequate kinetic energy so that they also move into the space in front of the cathode 16 and form a coating there on the article 12. As a result of the substrate bias the inert gas ions are likewise attracted to the substrates, i.e. to the workpieces and serve to increase the density of the coating. It will be understood that this bias which is applied to the substrates operates in such a way that it attracts the ions of the cathode material which are knocked out of the surface of the cathode and which are present in the plasma in front of the cathode 16.

Sputtering processes are known in different embodiments. There are those with a constant negative voltage at the cathode 16 and with a constant negative bias at the substrate holder. This is described as DC magnetron sputtering. Pulsed DC sputtering is also known in which at least one of the cathode supplies is operated in a pulsed mode. In addition the bias supply for the substrate carrier can likewise be operated in a pulsed mode. This can in particular be of advantage with cathodes of a semi-insulating material.

In such a DC magnetron sputtering process the power which can be consumed by each cathode 16 lies for example between 16 and 20 kW.

In more recent time the cathodes are however no longer supplied with a constant DC current but rather a much higher power is used, which is however only applied in relatively short impulses. For example the power impulses as shown in FIG. 2 can be generated by the HIPIMS power source 18 with a time duration of 10 μs and a pulse repetition time of 200 μs corresponding to a pulse repetition frequency of 5000 Hz, i.e. an interval between sequential pulses of 190 μm. The values quoted are to be understood purely as by way of example and can be varied in wide limits. For example, one can operate straightforwardly with an impulse duration in the range between 10 μm and 30 ms and with a pulse repetition time between 200 μs and 100 ms. As the time in which a very high power is applied to the cathodes is restricted, the average power can be kept at a moderate level corresponding to the power level during normal magnetron sputtering in the DC mode. It has however been found that by the application of high power impulses to the cathode or cathodes these operate in a different operating mode in which a very high degree of ionization of the metal vapor arises which emerges from the cathode or the cathodes, with this degree of ionization being able to lie straightforwardly in the range between 40% and indeed up to 100%. As a result of this high degree of ionization many more ions are attracted by the substrates and arrive there with higher speed, which leads to denser coatings and a more rapid coating process.

The fact that the power is concentrated in the power peaks however also leads to relatively high currents in the bias voltage supply for the substrates while these power peaks are flowing and the current take-up cannot be straightforwardly delivered by a normal bias power supply.

In order to overcome this difficulty, in accordance with the solution which is shown in WO 2007/115819, which is here indicated in FIG. 1, an additional voltage source 60 is provided. This voltage source 60 is most simply realized by a capacitor which is charged up by a customary power supply and indeed to a voltage which corresponds to the desired output voltage. When a power impulse is applied from the HIPIMS power source 16 to the cathode 10 this leads, as mentioned above, to a material flux, which consists essentially of ions from the cathode 16 and is directed to the substrates 12. This increase of the ion flux signifies an increase of the current at the substrate holder 20 and through the line 27 of, for example, 40 amperes. A normal bias power supply 32 could not deliver such high peak current when this is designed for DC operation instead of for a HIPIMS operation. However, the capacitor 62 which is charged up by the bias voltage supply in pauses between the individual high power impulses of the cathode supply 18, is able to hold the desired bias voltage at the substrate holder within narrow limits and to deliver the required current, which only causes a small discharging of the capacitor. In this way the substrate bias voltage remains at least substantially constant.

By way of example the discharge can take place in such a way that a bias voltage that is provided of, for example, −50 V, drops during the coating process to, for example, −40 V.

It should be pointed out that further undesired voltage drops also occur during the etching process in which the bias voltage of the substrate carrier and of the substrates lie at much higher values, for example from somewhat below −700 V to −1200 V.

The bias power supply 32 in the form shown in FIG. 1 is therefore basically able to enable a HIPIMS magnetron sputtering process.

For the sake of completeness it should be pointed out that the bias power supply 32 can also be provided with an arc protection function. By way of example, detectors such as 64 can be provided which detect the current flowing in the line 32 and can be used to actuate a semiconductor switch 34 in order, in the case of an arc arising, to open the switch 34 and thus to interrupt the bias voltage at the substrate holder 20 or carrier and hereby to bring about the extinguishing of the arc. The broken line in the detector 66′ shows an alternative position for the detector 66 which is here realized as a voltage detector. Further modifications and embodiments are described in the named WO 2007/115819.

In the present application one is concerned with improving the etching process.

FIG. 3 shows a modified version of the embodiment of FIG. 1 in accordance with the invention. In this connection the same reference numerals are used in FIG. 3 as in FIG. 1 and these reference numerals also refer to the same components of the apparatus or of the plant. Furthermore, the description of FIG. 1 given with reference to the reference numerals applies in just the same way to FIG. 3 unless something else is stated. For the sake of simplicity only the differing design will now be discussed.

Whereas in the embodiment of FIG. 1 the cathode, for example 16 at the right hand side of the shown apparatus, is used for the etching process and is operated with the same pulse sequence as in FIG. 2 but with a bias voltage (bias potential) which is selected for the etching process with higher values, such as for example −700 to −1200 V, in the embodiment of FIG. 3 four cathodes 16A, 16B, 16C, 16D are used in place of a cathode 16. They can for example have a circular shape and each have a significantly smaller surface than the cathode 16 which they replace.

Whereas the cathode or cathodes 16 have a rectangular shape (which does not necessarily have to be the case) a circular shape is selected for the sake of simplicity for the etching cathodes 16A, 16B, 16C, 16D, with this however also not being essential. Instead the etching cathodes 16A, 16B, 16C, 16D could also have a square or rectangular or other shape. Circular magnetron cathodes are known per se as are the magnet systems which are used with them lead to the desired magnetic tunnel in front of the respective cathode and which here also has the form of a closed loop.

In accordance with the present teaching the coating apparatus 10 is provided with a vacuum chamber 14 a plurality of etching cathodes 16 and 16A, 16B, 16C, 16D arranged therein and also with a HIPIMS power source 18, the HIPIMS power source 18 being designed precisely as known in the prior art. The coating apparatus in accordance with FIG. 3 thus has, in addition to at least one coating cathode 16 (here shown at the left hand side of the apparatus) which can operate with the HIPIMS power source, the etching cathodes 16A, 16B, 16C, 16D which are of smaller area in comparison to the coating cathode 16 and which can be connected by means of the electronic switch 80 in a predetermined or predeterminable sequence to the HIPIMS power source 18.

The reference numeral 82 points to a further switch can be formed as an electronic switch like the switch 80, but which also can have a different design, such as for example a mechanical or electromagnetically operated switch. This applies in principle also for the switch 80.

The switch 80 consists in this embodiment of four individual switches 80A, 80B, 80C, 80D which are opened and closed at the clock frequency of the pulse sequence of the HIPIMS power source 18 in accordance with FIG. 2 and synchronized with it so that, as is also evident from FIG. 4, for example the first impulse of the sequence is applied to the cathode 16A, the second impulse of the sequence to the cathode 16B, the third impulse from the sequence to the etching cathode 16C, the fourth impulse of the impulse sequence to the etching cathode 16D and the fifth impulse of the impulse sequence is again applied to the etching cathode 16A etc.

As the individual etching cathodes 16A to 16D have a substantially smaller area than the coating cathode 16 a substantially higher peak current density can be achieved at the etching cathodes 16A to 16D. The cathodes are preferably switched on one after the other via the electronic switch 80 and 80A to 80D so that at a specific point in time only one cathode is in operation. Even though the individual etching cathodes 16A to 16D are clocked with the frequency of the impulse sequence of the HIPIMS power source 18 they can remain in each case switched on for a substantially longer period of time so that the power impulses can also build up and decay.

As expressed above there is not necessarily provided just one coating cathode 16 such as is shown at the left hand side of FIG. 3 but rather coating cathodes 16 can also be provided in the vacuum chamber which can be connected one after the other or simultaneously or in desired combinations via switches such as 82 to the HIPIMS power source 18. Further HIPIMS power sources can also be provided for the individual coating cathodes or groups thereof.

When it is stated here that in addition to at least one coating cathode 16 a plurality of etching cathodes which are of smaller area in comparison to the coating cathodes 16 are provided then this signifies that the etching cathodes are of smaller area than the individual coating cathodes and are at least smaller than the largest of the individual coating cathodes, should, for whatever reason, a smaller coating cathode also be provided, for example if only a smaller percentage of a specific element should be incorporated in the coating. Coating cathodes are frequently always provided with the same size, even though only a smaller percentage of an element of one of the coating cathodes is to be supplied, because this cathode can also last longer than the further coating cathodes, i.e. does not need to be exchanged so frequently. With a smaller coating cathode this is then also frequently operated with reduced power, so that the maximum current density in the coating process lies at an ideal value for the coating process.

The coating cathodes and the etching cathodes can consist of desired materials. Purely by way of example, the coating cathodes can consist of titanium, zirconium, aluminum, tungsten, chromium, tantalum or their alloys, optionally with smaller additions of other elements such as niobium or boron and also small additions of rare earth elements such as Sc, Y, La or Ce. Also carbon cathodes can be considered, for example graphite. As reactive gases consideration can be given, if required, to gases such as nitrogen or acetylene amongst other things.

It is particularly favorable when an inert gas such as neon, argon, krypton or zenon is used for the etching process and cathodes of chromium, vanadium, titanium, zirconium, molybdenum, tungsten, niobium or tantalum are provided for the etching process, i.e. the etching cathodes 16A to 16D can consist of these elements (i.e. Cr, V, Ti, Zr, Mo, W, Nb, Ta) or also of other elements or alloys so far as this is desired.

The etching process is normally carried out with an argon pressure in the range from 10⁻⁵ to 10⁻¹ mbar, preferably at about 10⁻² mbar.

The etching cathodes 16A to 16D could however also be used as coating cathodes. For this purpose the switches 80A to 80D can be simultaneously closed whereby the etching cathodes 16A to 16D are connected in parallel to a HIPIMS power source 18. In this respect the switch 82 can be closed or opened.

As is evident from FIG. 5, the HIPIMS power source normally consists of a DC part 84 and a switching part 86 which generates power impulses from the output power of the DC part 84 with the desired or predeterminable frequency, such as are shown in FIG. 2 for the coating cathode. As expressed above, when operating the coating apparatus in the etching mode, as shown in FIG. 3, the power impulses at the predetermined frequency are applied to the individual etching cathodes 16A, 16B, 16C, 16D in a predetermined or predeterminable sequence, here in the sequence 16A, 16B, 16D, 16D whereby the etching cathodes are successively fed with the individual power impulses of a HIPIMS power source. Other sequences are also conceivable such as for example 16A, 16C, 16B, 16D and it is certainly not necessarily the case that only four etching cathodes are used. In principle any desired number of etching cathodes can be used they also do not all have to have the same size.

The present teaching is presented numerically here with reference to an embodiment with four etching cathodes of the same size and one coating cathode. In accordance with an example of the invention the coating cathode 16 can be rectangular with a length and width of 100 cm×17 cm, i.e. an area of 1700 cm². A coating cathode of this kind is normally operated in the HIPIMS mode with 360 kW and a peak current of 600 A. This results, with a surface of approximately 1700 cm² in a power density of approximately 212 W per cm² and a current density of approximately 0.35 A/cm². If one considers an etching cathode with a diameter of 17 cm then for each etching cathode an area of about 345 cm² results and this signifies for the same power supply a power per unit area or power density of approximately five times more, i.e. 1.04 kW/cm² and a current density of 1.7 A/cm².

The coating apparatus of the HIPIMS power source can also be designed differently. For example the switching part 84 can be so designed or controlled that the HIPIMS power source 18 can be operated in the etching mode so that it delivers at least further impulses in addition to the power impulses with the predetermined frequency, i.e. power impulses with a higher frequency. These power impulses are then delivered, for example in accordance with FIG. 6, in sequence to the etching cathode. FIG. 6 shows this only for the first five impulses, here in the pulse sequence 16A, 16B, 16C, 16D, 16A to the etching cathodes 16A, 16B, 16C, 16D. In other respects the pulse sequence of FIG. 3 is shown for the sake of representation but in reality three additional power impulses are delivered by the switching part 86 between each two sequential power impulses with larger spacing, as is actually shown in FIG. 7. In the example of FIG. 6 the etching cathodes 16A, 16B, 16C and 16D are also successively fed with the individual pulses of the HIPIMS power source.

This is, however, not necessarily the case. FIG. 7 shows in another embodiment how another association of the power impulses to the etching cathodes can be effected and indeed in such a way that here the first four impulses are fed to the etching cathode 16A, the next four power impulses to the etching cathode 16B, the next four power impulses to the etching cathode 16C, the next four power impulses for the etching cathode 16D etc. I.e., in other words, the HIPIMS power source is so operated in the etching mode that it delivers at least further impulses between the power impulses with the predetermined frequency and in that the impulses that are delivered in total are applied in groups to the etching cathodes in sequence, whereby the etching cathodes can be successively fed with the individual groups of impulses. The number of the power impulses in the individual groups is not restricted to four and any desired groups and sequences of the energized etching cathodes can be selected. The operation of the switching part of higher frequency can also lead to an increase of the power of the DC part 84. This is however within limits. Advantageously the etching process can be shortened as a result of the higher impulse frequency.

1-7. (canceled)

8. A coating apparatus (10) having a vacuum chamber (14), a plurality of cathodes (16, 16A, 16B, 16C, 16D) arranged therein and also a HIPIMS power source (18) wherein, in addition to at least one coating cathode (16) which can be operated with the HIPIMS power source a plurality of etching cathodes (16A, 16B, 16C, 16D) is provided which are smaller in area in comparison to the coating cathode, with the etching cathodes being connectable in a predetermined or predeterminable sequence to the HIPIMS power source (18).

9. A coating apparatus in accordance with claim 8,
wherein the etching cathodes (16A, 16B, 16C, 16D) are each individually connectable to the HIPIMS power source (18) in the etching mode via a switching device (80, 80A, 80B, 80C, 80D).

10. A coating apparatus in accordance with claim 8,
wherein the etching cathodes (16A, 16B, 16C, 16D) can also be used as coating cathodes.

11. A coating apparatus in accordance with claim 10,
wherein the etching cathodes (16A, 16B, 16C, 16D) are connectable jointly to the HIPIMS power source (18) for the coating process.

12. A coating apparatus in accordance with claim 10,
wherein the etching cathodes (16A, 16B, 16C, 16D) are connectable in parallel to the HIPIMS power source (18) for the coating process.

13. A coating apparatus in accordance with claim 8, wherein
the HIPIMS power source (18) consists of a DC part (84) and a switching part (86) which generates power impulses with a predetermined frequency for the coating cathode (16) from the DC part and wherein, when operating the coating apparatus in the etching mode, the power pulses with the predetermined frequency are applied to the individual etching cathodes (16A, 16B, 16C, 16D) in a predetermined or predeterminable sequence, whereby the etching cathodes are successively fed with the individual power pulses of the HIPIMS power source (18).

14. A coating apparatus in accordance with claim 8, wherein
the HIPIMS power source (18) consists of a DC part (84) and a switching part (86) which generates power pulses with a predetermined frequency for the coating cathode from the DC part, wherein the HIPIMS power source (18) can be so operated in the etching mode that it delivers at least further pulses between the power pulses with the predetermined frequency and wherein the impulses which are delivered in total are applied to the etching cathodes (16A, 16B, 16C, 16D) one after the other, whereby the etching cathodes (16A, 16B, 16C, 16D) can be successively fed with the individual pulses of the HIPIMS power source (18).

15. A coating apparatus in accordance with claim 8, wherein a HIPIMS power source (18) consists of a DC part (84) and a switching part (86) which generates power pulses with a predetermined frequency for the coating cathode (16) from the DC part, wherein the HIPIMS power source (18) can be so operated in the etching mode that it delivers at least further pulses between the power pulses with the predetermined frequency and wherein the pulses that are delivered in total are applied in groups to the etching cathodes (16A, 16B, 16C, 16D) in sequence, whereby the etching cathodes are successively fed with the individual groups of pulses.
